(19) United States
(12) Patent Application Publication
(10) Pub. No.: US 2010/0330773 A1
(43) Pub. Date: Dec. 30, 2010

(54) SUBSTRATE PROCESSING METHOD AND SUBSTRATE PROCESSING APPARATUS

(75) Inventor: Shin HIYAMA, Toyama-shi (JP)

Correspondence Address: BRUNDIDGE & STANGER, P.C., 2318 MILL ROAD, SUITE 1020, ALEXANDRIA, VA, 22314, US

(73) Assignee: HITACHI-KOKUSAI ELECTRIC INC., Tokyo (JP)

(21) Appl. No.: 12/822,304

(22) Filed: Jun. 24, 2010

(30) Foreign Application Priority Data
Jun. 30, 2009 (JP) 2009-155146
Apr. 27, 2010 (JP) 2010-102004

(51) Int. Cl. H01L 21/31; B05C 11/10

(52) U.S. Cl. 438/400; 438/758; 118/695; 257/E21.24

(57) ABSTRACT

Provided is a substrate processing method, which can fill an insulating film in a groove having a small width with a high aspect ratio and improve the productivity. The substrate processing method comprises loading a substrate into a processing chamber, supplying silicon compound gas including carbon and hydrogen into the processing chamber, irradiating ultraviolet light on the silicon compound gas supplied into the processing chamber to process the substrate, unloading the processed substrate from the processing chamber, and processing the inside of the processing chamber with excited oxygen-containing gas. Accordingly, an adhered matter generated when irradiating the ultraviolet light on the silicon compound gas to process the substrate and adhered to a structure such as an inner wall of the processing chamber can be processed with the excited oxygen-containing gas to modify it.

### CROSS-REFERENCE TO RELATED PATENT APPLICATION

This U.S. non-provisional patent application claims priority under 35 U.S.C. §119 of Japanese Patent Application Nos. 2009-155146, filed on Jun. 30, 2009, and 2010-102004, filed on Apr. 27, 2010, in the Japanese Patent Office, the entire contents of which are hereby incorporated by reference.

### BACKGROUND OF THE INVENTION

1. Field of the Invention

The present invention relates to a substrate processing technology using ultraviolet light, and more particularly, to a substrate processing technology in an apparatus or a method for manufacturing a semiconductor integrated circuit device (semiconductor device, referred to as an ‘IC’ hereinafter), which is effective in depositing a structure such as an oxide film on a semiconductor substrate (for example, a semiconductor wafer) provided with a semiconductor integrated circuit (semiconductor device) to perform a process such as a film forming process.

2. Description of the Related Art

In manufacturing integrated circuits (ICs), as ICs is highly integrated, miniaturization of elements constituting the ICs is required. Especially, as a device isolation forming method for ICs, a shallow trench isolation (STI) method having an excellent dimension control property and providing a small occupation area is currently used. In the STI method, after a groove is formed in a semiconductor substrate, an atmospheric pressure chemical vapor deposition (CVD) method using tetraethoxysilane (TEOS) and O₃ (ozone), or a plasma CVD method using TEOS is used to fill an insulating film into the formed groove, thereby forming a device isolation region.

However, in recent years, high integration of ICs is gradually increased, and the width of a device isolation groove is 0.1 μm or less, and simultaneously, an aspect ratio, which is a ratio of the depth of a device isolation groove to the width thereof, is increased. For this reason, in the atmospheric pressure CVD method used in the related art, it is difficult to fill an insulating film in a device isolation groove without forming a void or a seam, which will be described later.

As one reason for this limitation, in a related art method such as the atmospheric pressure CVD method, a film forming speed of an insulating film on an opening in a groove is higher than a film forming speed on a deep part in the groove. Since the film forming speed on the opening in the groove is higher than the film forming speed on the deep part of the groove, before the insulating film is sufficiently filled in the deep part of the groove, the opening is closed with the insulating film. As such, the phenomenon that an opening in a groove is formed thicker than a deep part of the groove is called overhang.

The reason why a film forming speed of an insulating film on an opening in a groove is higher than a film forming speed on a deep part of the groove is as follows. In the atmospheric pressure CVD method or the plasma CVD method used in the related art, material gas is decomposed, for example, with heat, and a chemical reaction occurs in vapor phase, so that a reaction product is adhered to a substrate, thereby forming an insulating film. For this reason, a film forming speed is rate-determined by a supply speed of material gas, a reaction speed of material gas in vapor phase, and a substrate adherence probability of a reaction product.

Under a supply rate determination condition that the adherence probability of a reaction product to a substrate approaches 1, since a film forming speed of an insulating film on an opening in a groove is higher than a film forming speed on a deep part of the groove, the opening in the groove is closed with the insulating film before sufficiently filling the deep part in the groove with the insulating film, so as to form an empty space that is called a void. Also under a supply rate determination condition that the adherence probability of a reaction product to a substrate approaches 0, since a film to be formed grows from both side walls of a groove, a slit shaped defect, which is called a seam, occurs in a contact of film parts growing on both the side walls. The phenomenon called the seam is inevitable even in an atomic layer deposition (ALD) method that has, in principal, a step coverage of 100%.

A substrate processing apparatus related with the ALD method corresponding to a miniaturization technology is disclosed, for example, in Patent Document 1 below.

[Patent Document 1]

Japanese Unexamined Patent Application Publication No. 2006-80291

When an opening in a groove is closed due to the overhang, for example, in a high density plasma (HDP) CVD method, after forming a film, ion etching using inert gas such as argon may be performed to etch the overhang formed while forming the film, thereby recovering the opening in the recess. However, even in this method, when a groove has a width of 65 nm or less, that is, an aspect ratio of 5 or greater, it is difficult to fill an insulating film in a deep part of the groove without forming a void.

### SUMMARY OF THE INVENTION

An object of the present invention is to provide a substrate processing method in which an insulating film can be filled in a groove having a small width with a high aspect ratio using a photo induced CVD method, and a substrate processing method and a substrate processing apparatus, which can improve the throughput and form a high quality film.

According to an aspect of the present invention, there is provided a substrate processing method in a substrate processing apparatus including: a processing chamber configured to process a substrate; a ultraviolet light emitting part installed out of the processing chamber to irradiate ultraviolet light into the processing chamber; and a transmission window installed on a partition wall of the processing chamber to transmit the ultraviolet light, the substrate processing method comprising: loading the substrate into the processing chamber; supplying silicon compound gas including carbon and hydrogen into the processing chamber; irradiating the ultraviolet light on the silicon compound gas supplied into the processing chamber to process the substrate; unloading the processed substrate from the processing chamber; and processing the transmission window with excited oxygen-containing gas.

According to another aspect of the present invention, there is provided a substrate processing apparatus comprising: a processing chamber configured to process a substrate; a first gas supply part configured to supply silicon compound gas including carbon and hydrogen into the processing chamber; a second gas supply part configured to supply oxygen-containing gas into the processing chamber; a ultraviolet light emitting part installed out of the processing chamber to irradiate ultraviolet light into the processing chamber; a transmission window installed on a partition wall of the processing chamber to transmit the ultraviolet light; and a control part, wherein the control part performs, in a state where the substrate is disposed in the processing chamber, a first process of irradiating the ultraviolet light from the ultraviolet light emitting part on the silicon compound gas supplied from the first gas supply part into the processing chamber, and the control part performs, in a state where the substrate is disposed out of the processing chamber, a second process of processing an inside of the processing chamber with the oxygen-containing gas supplied from the second gas supply part into the processing chamber and excited.

According to another aspect of the present invention, there is provided a semiconductor device manufacturing method comprising: loading a semiconductor substrate into a processing chamber; supplying silicon compound gas including carbon and hydrogen into the processing chamber; irradiating ultraviolet light on the silicon compound gas supplied into the processing chamber to process the substrate; unloading the processed substrate from the processing chamber; and processing an inside of the processing chamber with excited oxygen-containing gas.

### BRIEF DESCRIPTION OF THE DRAWINGS

FIG. 1 is a vertical cross-sectional view illustrating a configuration of a substrate processing apparatus capable of performing a substrate processing method according to an embodiment of the present invention.

FIG. 2 is a graph illustrating effects according to an embodiment of the present invention.

### DETAILED DESCRIPTION OF THE PREFERRED EMBODIMENTS

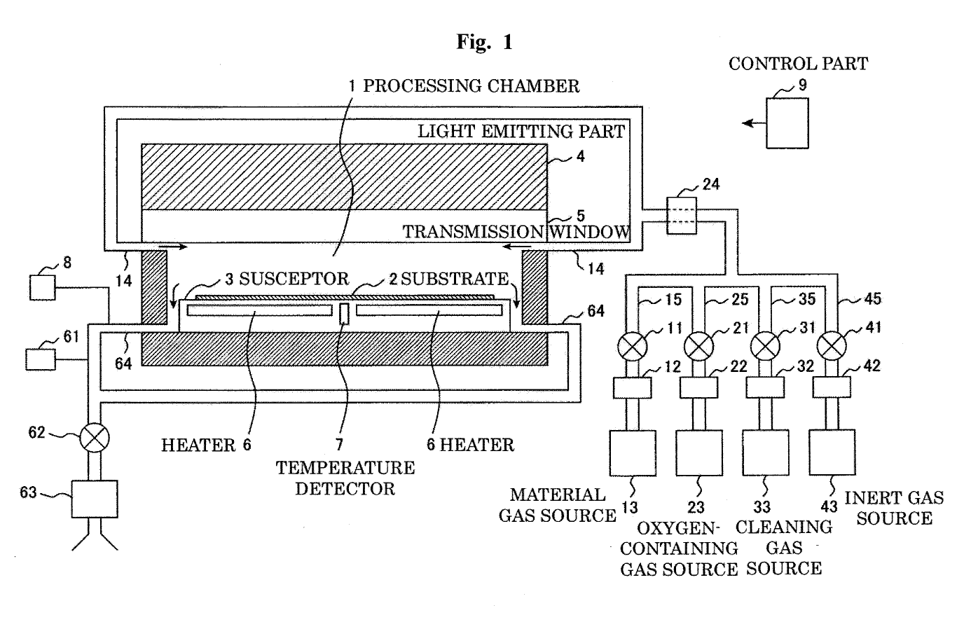

A configuration of a substrate processing apparatus performing a substrate processing process according to the present invention will now be described with reference to FIG. 1. FIG. 1 is a vertical cross-sectional view illustrating a configuration of a substrate processing apparatus capable of performing a substrate processing method according to an embodiment of the present invention. Referring to FIG. 1, reference numeral 1 denotes a substrate processing chamber configured to processing a substrate therein, and reference numeral 2 denotes a substrate to be processed. In the current embodiment, a single substrate is processed through a single process. Reference numeral 3 denotes a substrate stage part on which the substrate 2 is placed when the substrate 2 is processed. Reference numeral 4 denotes a light emitting part configured to emit ultraviolet light out of the substrate processing chamber 1. Reference numeral 5 denotes a transmission window configured to transmit ultraviolet light emitted from the light emitting part 4 into the substrate processing chamber 1, and the transmission window 5 is made of quartz in the current embodiment. The transmission window 5 is configured as a part of a partition wall to separate the inside and outside of the substrate processing chamber 1. Reference numeral 6 denotes a heater unit configured to heat the substrate 2, and the heater unit 6 is configured as a resistance heater in the current embodiment. Reference numeral 7 denotes a temperature detector configured to detect a temperature of the substrate 2. Reference numeral 8 denotes a remaining gas measurement device configured to measure a partial pressure of organic materials (carbon and hydrogen) to measure a remaining amount of the organic materials (carbon and hydrogen) of remaining gas. Reference numeral 9 denotes a control part configured to control factors such as an inner pressure of the substrate processing chamber 1. The heater unit 6 and the temperature detector 7 are electrically connected to the control part 9. The control part 9 controls the power condition of the heater unit 6 based on temperature information detected using the temperature detector 7 to maintain the substrate 2 at a desired temperature distribution at a desired time.

In the substrate processing apparatus, an excimer lamp is disposed in the light emitting part 4, and simultaneously, is filled with rare gas such as argon (Ar₂), krypton (Kr₂), and xenon (Xe₂). By filling such rare gas, a wavelength of ultraviolet light can be set. For example, ultraviolet light having a wavelength of 126 nm may be emitted when filling Ar₂, and ultraviolet light having a wavelength of 146 nm may be emitted when filling Kr₂, and ultraviolet light having a wavelength of 172 nm may be emitted when filling Xe₂. In the current embodiment, Xe₂ is filled to generate ultraviolet light. The generated ultraviolet light is supplied into the substrate processing chamber 1 through the transmission window 5 made of quartz.

The substrate processing chamber 1 are air-tightly separated from the light emitting part 4 by the transmission window 5 made of quartz. Thus, the rare gas in the light emitting part 4 is prevented from being discharged to the substrate processing chamber 1, and gas such as silicon compound gas in the substrate processing chamber 1 is prevented from being introduced to the light emitting part 4.

Next, a gas supply system configured to supply gas such as process gas will now be described. As shown in FIG. 1, a gas introduction pipe 14 of the substrate processing chamber 1 is connected with a silicon compound gas supply pipe 15, an oxygen-containing gas supply pipe 25, a cleaning gas supply pipe 35, and an inert gas supply pipe 45. At the silicon compound gas supply pipe 15, sequentially from an upstream side of a gas flow, a silicon compound gas source 13 configured to supply silicon compound gas including carbon and hydrogen, a mass flow controller (MFC) 12 as a flow rate control device, and an opening-closing valve 11 are installed. At the oxygen-containing gas supply pipe 25, sequentially from an upstream side of a gas flow, an oxygen-containing gas source 23 configured to supply oxygen-containing gas, an MFC 22, and an opening-closing valve 21 are installed. At the cleaning gas supply pipe 35, sequentially from an upstream side of a gas flow, a cleaning gas source 33 configured to supply cleaning gas such as NF₃ gas, an MFC 32, and an opening-closing valve 31 are installed. At the inert gas supply pipe 45, sequentially from an upstream side of a gas flow, an inert gas source 43 configured to supply inert gas such as N₂ (nitrogen) gas, an MFC 42, and an opening-closing valve 41 are installed.

A high frequency application part 24 is installed between the oxygen-containing gas supply pipe 25 and the introduction pipe 14, or between the cleaning gas supply pipe 35 and the introduction pipe 14. The high frequency application part 24, for example, applies a high frequency power to gas flowing from the cleaning gas supply pipe 35 to the introduction pipe 14 and excites the flowing gas into plasma, so as to activate cleansing gas. Alternatively, the high frequency application part 24 applies a high frequency power to gas flowing from the oxygen-containing gas supply pipe 25 to the introduction pipe 14 and excites the flowing gas into plasma, so as to activate oxygen-containing gas.

The MFCs 12, 22, 32, and 42, and the opening-closing valves 11, 21, 31, and 41 are electrically connected to the control part 9. The control part 9 controls the MFCs 12, 22, 32, and 42, and the opening-closing valves 11, 21, 31, and 41 such that gas is supplied into the substrate processing chamber 1 with a desired type at a desired time, and such that gas supplied into the substrate processing chamber 1 has a desired flow rate at a desired time.

As silicon compound gas including carbon and hydrogen, for example, one of TEOS (tetraethoxysilane: Si(OC₂H₅)₄), TMCTS (tetramethylcyclotetrasiloxane: [(CH₃)HSiO]₄), OMCTS (octamethylcyclotetrasiloxane: [(CH₃)₂SiO]₄), OMTS (octamethylcyclotetrasiloxane: Si₂O₂(CH₃)₈), HNDSO (hexamethyldisiloxane: [(CH₃)₂SiOSi(CH₃)₃]), TMOS (tetramethoxysilane: Si(OCH₃)₄), HMCTSN (hexamethylcyclotrisilazane: Si₃C₃H₂₁N₃), and HMCTS (hexamethylcyclotrisiloxane: [SiO(CH₃)₂] may be used.

In addition, when silicon compound gas is supplied into the substrate processing chamber 1, inert gas may also be supplied as carrier gas or diluent gas if necessary. As the inert gas, for example, argon, helium, or nitrogen gas may be used.

Next, a gas exhaust system of the substrate processing chamber 1 will now be described. As shown in FIG. 1, at a gas exhaust pipe 64 configured to exhaust inner atmosphere of the substrate processing chamber 1, sequentially from an upstream side of a gas flow, a remaining gas measurement device 8, a pressure sensor 61, an auto pressure controller (APC) valve 62 as a pressure adjustment valve, and a vacuum pump 63 as a vacuum exhaust device are installed. The vacuum pump 63 is configured to evacuate the substrate processing chamber 1 such that an inner pressure of the substrate processing chamber 1 reaches a predetermined pressure (degree of vacuum). The APC valve 62 and the pressure sensor 61 are electrically connected to the control part 9. The control part 9 is configured to control degree of valve opening of the APC valve 62 based on a pressure value detected using the pressure sensor 61 to maintain an inner pressure of the substrate processing chamber 1 at a desired pressure at a desired time.

The control part 9 includes a manipulation part, a display part, and an input/output part, which are not shown, and is connected to each part of the substrate processing apparatus, and controls each part. The control part 9, based on a recipe (a control sequence of a film forming process), controls an inner temperature or pressure of the substrate processing chamber 1, a flow rate of process gas, and mechanical driving such as loading of a substrate into the substrate processing chamber 1. In addition, the control part 9 includes, as a hardware configuration, a central processing unit (CPU) and a memory configured to store an operation program of a CPU or a recipe.

Next, a substrate processing method will now be described according to an embodiment of the present invention.

(A) Trench Forming Process

First, on a silicon substrate, an etching pattern of a trench (groove) that is formed in a device isolation region, for example, using a shallow trench isolation (STI) method is formed. After that, a dry etching operation is performed to form a groove having a desired depth on the silicon substrate.

(B) Substrate Loading Process

Next, a substrate 2 having the recess through the trench forming process is placed on a susceptor 3 in the substrate processing chamber 1 through a substrate loading port (not shown) of the substrate processing apparatus shown in FIG. 1. Subsequently, through the gas exhaust pipe 64, the vacuum pump 63 is used to decrease the inner pressure of the substrate processing chamber 1 to a predetermined degree of vacuum (for example, 20 Pa), and the heater unit 6 is used to heat the substrate 2 to a predetermined temperature (for example, 80° C.)

(C) Film Forming Process

Next, in a film forming process, predetermined material gas based on organic silicon (silicon compound gas including carbon and hydrogen) is supplied from the silicon compound gas source 13 through the introduction pipe 14 to the substrate processing chamber 1. At this time, inert gas such as nitrogen gas may be supplied from the inert gas source 43 to the substrate processing chamber 1. In a state where the material gas is supplied to the substrate processing chamber 1, the vacuum pump 63 is used to adjust the inside of the substrate processing chamber 1 to a predetermined pressure, and ultraviolet light is irradiated from the light emitting part 4 to the material gas. The organic silicon, which is the material gas, is in an Si—O—Si—R bond state (where R is a lower alkyl group). By irradiating the ultraviolet light, Si—O—Si—R bonds are broken, that is, R is removed to form siloxane (Si—O bond), and simultaneously, the siloxane is excited and polymerized to generate a silicon oxide film including polysiloxane (Si—O bond). At this time, by setting the intensity of the ultraviolet light, irradiated on a surface of the substrate 2, as 3 mW/cm² or greater, a film forming speed is improved, and fluidity of the film can be secured while forming the film such that the film has a flat surface.

Here, the fluidity of the film is understood as easy mobility of a reaction product adhered to a substrate. The reaction product adhered to the substrate has, due to boundary tension, a tendency to move on the substrate to a region in which its density is low, and has a tendency to be flat. Thus, as the fluidity of a film increases, it is easy to form a film down to a deep part of a groove.

In the film forming process, it is preferable that the substrate 2 may be maintained at a temperature ranging from 0° C. to 100° C., and the inside of the substrate processing chamber 1 may be maintained at a pressure ranging from 20 Pa to 100 Pa. In the current embodiment, the substrate 2 is maintained at a temperature of 50° C., and the inside of the substrate processing chamber 1 is maintained at a pressure of 40 Pa. If the inner pressure of the substrate processing chamber 1 is less than 20 Pa, the film forming speed is low and impractical. In addition, the density of the reaction product adhered to a substrate is small, the fluidity of a film to be formed is low. Under a pressure greater than 100 Pa, the energy per molecule of material gas is small, and the decomposition of gas is difficult.

In the film forming process, the silicon oxide film is formed on the inner wall of the substrate processing chamber 1 or the inner surface of the transmission window 5 (at the side adjacent to the substrate processing chamber 1) as well as the surface of the substrate 2. Since the formed film contains a hydrocarbon component included in the material gas, for example, a methyl group (CH₃) or an ethyl group (C₂H₅), the formed film has a tendency to absorb ultraviolet light. Thus, since the film formed on the inside of the transmission window 5 absorbs the ultraviolet light irradiated from the light emitting part 4 to the substrate processing chamber 1, as the thickness of the film formed on the transmission window 5 increases, the luminance (intensity) of the ultraviolet light irradiated on the substrate decreases, and thus, the forming speed of the film generated on the substrate 2 decreases.

In the above-described example, the ultraviolet light is irradiated while supplying the material gas to the substrate processing chamber 1, but the ultraviolet light may irradiated in a state where supplying of the material is stopped after the material gas is supplied to the substrate processing chamber 1.

Under a film forming condition that the fluidity of a film to be formed is high (under a relatively high pressure condition), a remaining organic concentration (concentration of carbon or hydrogen) of a formed film is high, and a remaining organic material may be excluded in a post process to cause a void. In this way, since a remaining organic concentration of a film is decreased, the control part 9 may perform the following controls in the film forming process (C).

(C1) First, while material gas is supplied and ultraviolet light is irradiated, at a pressure equal to or less than 10 Pa, which is a pressure equal to or less than a fluidity limit, that is, at a pressure under which the fluidity of a film to be formed is low, a film having a thickness ranging from about 1 to 2 nm is formed. In this case, since the energy per molecule of the material gas is large, a formed film can have excellent adhesion to silicon of the substrate 2, a low remaining organic material concentration, and high heat resistance.

(C2) Next, while the material gas is supplied and the ultraviolet light is irradiated, at a predetermined pressure (20 Pa to 100 Pa) under which a high film forming speed can be obtained, at a predetermined substrate temperature (0° C. to 100° C.), a film is formed up to a predetermined film thickness, for example, up to about one fourth the width of a groove.

(C3) The supplying of the material gas and the irradiation of the ultraviolet light are stopped, and then, the inner atmosphere of the substrate processing chamber 1 is exhausted. Accordingly, a remaining organic material concentration included in the film can be reduced. At this time, it is preferable that the evacuation may be performed together with monitoring at the remaining gas measurement device 8 until a partial pressure of the organic material under the evacuation reaches a predetermined partial pressure. For the predetermined partial pressure, an appropriate value is determined in advance, for example, through an experiment.

(C4) After the inner atmosphere of the substrate processing chamber 1 is exhausted, the material gas is supplied and the inside of the substrate processing chamber 1 reaches the predetermined pressure (20 Pa to 100 Pa) and the predetermined substrate temperature (0° C. to 100° C.), and then, the ultraviolet light is irradiated from the light emitting part 4 to the material gas. Accordingly, the film is formed a predetermined film thickness, for example, the predetermined film thickness is about three fourth the groove width.

(C5) The supplying of the material gas and the irradiation of the ultraviolet light are stopped, and then, the inner atmosphere of the substrate processing chamber 1 is exhausted. At this time, when a partial pressure of the organic material under the evacuation reaches a predetermined partial pressure, the evacuation is ended.

(C6) After the inner atmosphere of the substrate processing chamber 1 is exhausted, the material gas is supplied and the inside of the substrate processing chamber 1 reaches the predetermined pressure (20 Pa to 100 Pa) and the predetermined substrate temperature (0° C. to 100° C.), and then, the ultraviolet light is irradiated from the light emitting part 4 to the material gas. Accordingly, the film is formed up to a predetermined film thickness, that is, until the entire groove is completely filled.

As in the process from (C2) to (C6), by repeating the film forming and the evacuation, a flat insulating film with a small amount of a remaining organic material can be formed down to a deep part of the groove.

In (C2), (C4), and (C6), both the pressures and the substrate temperatures may be the same pressures and the same substrate temperatures, or may be different pressures and different substrate temperatures if necessary. For example, since the groove in (C6) has a less width than the width in (C2), it is preferable that the pressure is increased in (C6) to improve the fluidity of the film to be formed.

(D) Substrate Unloading Process

After a desired insulating film is formed as described above, inert gas such as nitrogen gas is supplied from the inert gas source 43 to the substrate processing chamber 1, and the inside of the substrate processing chamber 1 is replaced by the inert gas, and returns to the atmospheric pressure, and then, the processed substrate 2 is unloaded out of the substrate processing chamber 1.

(E) Modification Processing Process

Next, the sequence of the substrate loading process (B), the film forming process (C), and the substrate unloading process (D) is performed at one or more times to form films on one or more substrates 2, and then, a modification processing process (E) to be described as follows is performed.

After the processed substrate 2 is unloaded out of the substrate processing chamber 1, in the state where the substrate 2 is not present in the substrate processing chamber 1, oxygen-containing gas is supplied from the oxygen-containing gas source 23 through the introduction pipe 14 to the substrate processing chamber 1, and the inside of the substrate processing chamber 1 is adjusted to a predetermined pressure. In the current embodiment, the inner pressure of the substrate processing chamber 1 is 200 Pa. At this time, it may be unnecessary to heat the heater unit 6. After the inside of the substrate processing chamber 1 is adjusted to the predetermined pressure, the ultraviolet light is emitted from the light emitting part 4, and is irradiated into the substrate processing chamber 1 through the transmission window 5. The ultraviolet light irradiated into the substrate processing chamber 1 excites oxygen (O₂) of the oxygen-containing gas in the substrate processing chamber 1, so as to generate active oxygen. The generated active oxygen oxidizes a hydrocarbon component of an adhered matter (film) deposited on the inside of the substrate processing chamber 1 or on the inside of the transmission window 5, and thus, the hydrocarbon component is removed. Here, an operation of oxidizing the hydrocarbon component of the adhered matter to remove the hydrocarbon component is referred to as a modification processing operation. A reaction formula of the modification processing operation is expressed as the following formula (1),

CH₃+2O*→CO₂+H₂O Formula (1)

Accordingly, absorption of the ultraviolet light due to the deposited film can be suppressed, and illuminance reduction of the ultraviolet light irradiated into the substrate processing chamber 1 can be suppressed. Accordingly, transmissivity of the transmission window 5 can be maintained in a constant range, and thus, the film forming speed can be maintained in a constant range. It is preferable that the modification processing process (E) is performed while the illuminance (irradiation level) of the ultraviolet light on the substrate 2 is not reduced, for example, it is preferable that the modification processing process (E) is performed whenever the sequence of the processes (B), (C), and (D) is performed at two times.

Instead of the modification processing process (E), a cleaning process (F) to be described as follows may be performed. In this case, it is preferable that the sequence of the substrate loading process (B), the film forming process (C), and the substrate unloading process (D) is performed at one or more times to form films on one or more substrates 2, and then, the cleaning process (F) to be described as follows is performed.

In the film forming process (C), components respectively of silicon (Si), oxygen (O), carbon (C) and hydrogen (H) are adhered to the inside of the transmission window 5. Of these, the carbon (C) component and the hydrogen (H) component can be removed using the modification processing process (E), but the silicon (Si) component and the oxygen (O) component are not removed using the modification processing process (E). When adherence amounts of the silicon (Si) component and the oxygen (O) component increase, that is, when the thickness of a silicon oxide film adhered to the transmission window 5 increases, the silicon oxide film is detached to be a dust generation source. In addition, the thickness of a film or the irradiation intensity of ultraviolet light may be uneven. Thus, it is necessary to remove the silicon oxide film adhered to the transmission window 5 by using the cleaning process (F). Since the silicon oxide film including the carbon (C) component and the hydrogen (H) component can be removed in the cleaning process (F), the modification processing process (E) may be replaced with the cleaning process (F).

However, the cleaning process (F) includes a pre-coat processing operation (F2) as described later. The pre-coat processing operation (F2) has an even longer process time than that of the modification processing process (E). Thus, when the modification processing process (E) is replaced with the cleaning process (F), a process time of a substrate lot unit (for example, twenty five substrates) is increased, and the productivity (throughput time) is reduced.

Thus, it is preferable that the modification processing process (E) is performed with high frequency and the cleaning process (F) is performed with low frequency. For example, it is preferable that the modification processing process (E) is performed whenever the sequence of the processes (B), (C), and (D) is performed at two times, and the cleaning process (F) is performed whenever the sequence of the processes (B), (C), and (D) is performed at ten times.

(F) Cleaning Process

(F1: Cleaning Processing Operation)

In the substrate unloading process, after the processed substrate 2 is unloaded out of the substrate processing chamber 1, in the state where the substrate 2 is not present in the substrate processing chamber 1, for example, cleaning gas including fluorine such as NF₃ is supplied from the cleaning gas source 33 through the introduction pipe 14 to the substrate processing chamber 1. In addition, if necessary, while the cleaning gas is supplied, inert gas such as N₂ is supplied from the inert gas source 43 through the introduction pipe 14 to the substrate processing chamber 1. The inside of the substrate processing chamber 1 is adjusted to a predetermined pressure. In the current embodiment, an inner pressure of the substrate processing chamber 1 is 300 Pa. Accordingly, the cleaning gas is used to perform a cleaning processing operation of removing the adhered matter deposited on the inside of the substrate processing chamber 1 or the inner surface of the transmission window 5. The adhered matter is a silicon oxide film including silicon (Si) or oxygen (O). Using the cleaning processing operation, an adhered matter that is deposited on a structure such as the transmission window 5 and is not removed in the modification processing process (E) can be removed. It is preferable that the cleaning processing operation is performed before an adhered matter (silicon oxide) is detached, for example, whenever a substrate processing operation in which the thickness of a silicon oxide reaches 1 μm is performed, for example, whenever a substrate processing process is performed at 10 times. The cleaning gas is not limited to cleaning gas including fluorine.

When the cleaning processing operation is ended, the cleaning gas is exhausted from the gas exhaust pipe 64, and simultaneously, the inert gas is supplied from the inert gas source 43 through the introduction pipe 14 to the substrate processing chamber 1, and the cleaning gas in the substrate processing chamber 1 is replaced with the inert gas.

(F2: Pre-Coat Processing Operation)

When the film forming process (C) is performed just after the cleaning processing operation using the fluorine-containing gas is performed, remaining fluorine remaining in the substrate processing chamber 1 is reduced, and thus, to reproduce the processing condition, it is effective that the pre-coat processing operation is performed before the film forming process. The pre-coat processing operation is an operation that uses a silicon oxide film to cover a fluorine component adsorbed to the inner wall of the substrate processing chamber 1 by the cleaning processing operation. If the pre-coat processing operation is not performed, the following adverse effects (1), (2), (3), and (4) occur. (1) When a film is formed after the cleaning processing operation, a fluorine component is mixed with inner atmosphere of the substrate processing chamber 1, so as to negatively affect the quality of the film to be formed. (2) Fluorine varies heat radiation in the substrate processing chamber 1, so that the inner temperature of the substrate processing chamber 1 is unstable, and thus, a film forming speed is unstable. (3) Since material gas is easily adsorbed to the inner wall of the substrate processing chamber 1, the supply amount of the material gas to a substrate is unstable. (4) Since a silicon oxide film is not formed on the inner wall, the state of the substrate processing chamber 1 before the cleaning process (F) is performed varies. For this reason, the film processing operation in the film forming process (C) can not be reproduced. The adverse effects (1), (2), (3), and (4) can be removed using the pre-coat processing operation.

In the current embodiment, the pre-coat processing operation is performed as a part of the cleaning process (F). In the pre-coat processing operation, under a process condition (such as gas type, temperature, and pressure) that is similar to that of the film forming process (C), the similar film forming operation to that in the film forming process (C) is performed on one or more substrates. Alternatively, even when a different type of gas from that in the film forming process (C) is used, if the gas does not significantly affect a film forming process (that is, gas for forming a silicon oxide film), material gas thereof may be used to perform a film forming operation. As a substrate used in the pre-coat processing operation, an inexpensive preliminary film forming dedicated substrate may be used.

It is preferable that the modification processing process (E) is performed whenever the sequence of the substrate loading process (B), the film forming process (C) and the substrate unloading process (D) is performed at one time, but the modification processing process (E) may be performed whenever the sequence of the substrate loading process (B), the film forming process (C) and the substrate unloading process (D) is performed at a plurality of times.

In addition, it is preferable that the modification processing process (E) is performed whenever the sequence of the substrate loading process (B), the film forming process (C), and the substrate unloading process (D) is performed at a predetermined number of times, and, after the modification processing process (E) is performed at a plurality of times, the modification processing process (E) is replaced with the cleaning process (F). For example, a process is performed in the following sequence. That is, the sequence is defined as BCD(E) BCD(E) BCD(E) BCD(F) BCD(E) BCD(E) BCD(E) BCD(F). In detail, whenever a series of the BCD processes is performed at one time, the modification processing process (E) is performed at one time, and after the modification processing process (E) is performed totally at 3 times, the modification processing process (E) is replaced with the cleaning process (F). In this way, an adhered matter in a process chamber, which is cannot be removed by a modification processing operation using an oxygen-containing gas processing operation, can be removed using a fluorine-containing gas processing operation. In addition, by combining the fluorine-containing gas processing operation with the oxygen-containing gas processing operation to modify an adhered matter in the process chamber, the number of process times of the fluorine-containing gas processing operation having a longer process time than that of the oxygen-containing gas processing operation can be decreased, and thus, a process time of a substrate lot unit (for example, twenty five substrates) is decreased, and the productivity (throughput time) is improved.

In the modification processing process (E), oxygen (O₂) gas may be excited using the high frequency application part 24, instead of using the ultraviolet light, to apply a high frequency power to the oxygen (O₂) gas. Alternatively, ultraviolet light may be combined with the high frequency application part 24. In this case where the ultraviolet light is combined with the high frequency application part 24, a modification processing speed can be improved. Alternatively, ozone (O₃) gas may be used as the oxygen-containing gas. When the ozone (O₃) gas is used, production efficiency of active oxygen can be increased relative to a case of using O₂ gas, and thus, a modification processing speed can be improved.

In addition, in the cleaning process (F), when the cleaning gas is supplied from the cleaning gas source 33 through the introduction pipe 14 to the substrate processing chamber 1, the high frequency application part 24 may be used to apply a high frequency power to the cleaning gas to activate the cleaning gas. In this way, the cleaning performance of the cleaning gas is enhanced, and a cleaning process time can be reduced. In addition, ultraviolet light from the light emitting part 4 may be irradiated on cleaning gas supplied into the substrate processing chamber 1. In this way, the cleaning gas is activated in the substrate processing chamber 1, and thus, the activated cleaning gas is in a high energy state, so that the cleaning processing operation can be performed at a high speed and a cleaning process time can be reduced. When the ultraviolet light is irradiated on the cleaning gas, strongly activated cleaning gas damages the transmission window 5, and thus, a maintenance cycle of the substrate processing apparatus is shorten. Thus, to extend the maintenance cycle of the substrate processing apparatus, instead of irradiating the ultraviolet light on the cleaning gas, a remote plasma device may be used to activate the cleaning gas.

Moreover, when the remote plasma device is combined with the irradiation of ultraviolet light, the cleaning processing operation can be performed at a higher speed, and thus, the cleaning process time can be reduced. When the cleaning gas activated using the remote plasma device is supplied into the substrate processing chamber 1 and used in the cleaning processing operation, the service life in an activation state becomes increasingly shorter (activated energy is lost). Thus, since the cleaning gas activated using the remote plasma device is in a low energy state, a damage to the transmission window 5 is small, but the cleaning processing operation is performed at a low speed. By irradiating the ultraviolet light on the cleaning gas reaching the end of its activation service life, the cleaning gas is activated in the substrate processing chamber 1, and thus, is in a high energy state.

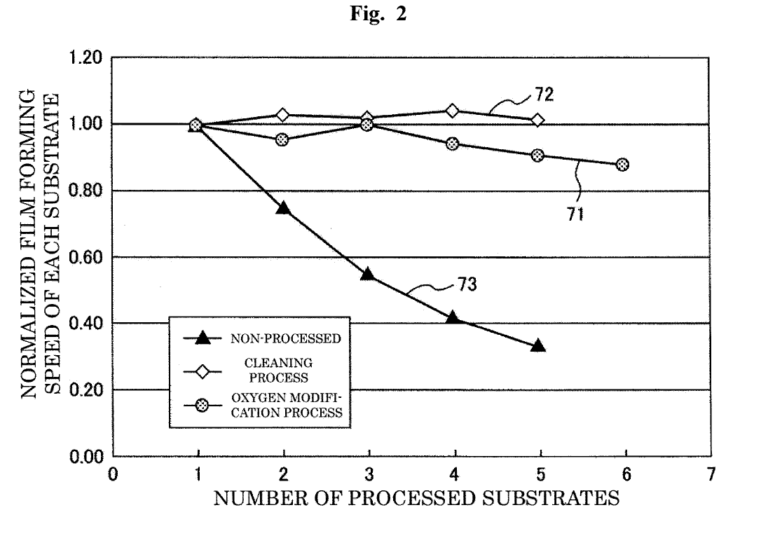

Effects of the modification processing operation according to the present invention are shown in FIG. 2. FIG. 2 is a graph illustrating effects according to an embodiment of the present invention. In FIG. 2, a horizontal axis denotes the number of processed substrates (the number of times of substrate processing operation), and a vertical axis denotes a relative film forming speed of each substrate when a film forming speed of a first substrate to be processed is determined as a reference value (1, 00). Reference numeral 71 denotes a film forming speed in the case where the modification processing operation according to the present invention is performed whenever the film forming operation is performed on a substrate 2. Reference numeral 72 denotes a film forming speed in the case where the cleaning processing operation is performed whenever the film forming process is performed on a substrate 2. Reference numeral 73 denotes a non-processed film forming speed without performing both the modification processing operation and the cleaning processing operation according to the present invention. When the modification processing operation and the cleaning processing operation are not performed, a film forming speed of a fifth substrate is reduced down to about 30% of a film forming speed of a first substrate, but when the modification processing operation according to the present invention is performed, a film forming speed of a fifth substrate is maintained at about 90% or greater of a film forming speed of a first substrate. In addition, when the cleaning processing operation using fluorine gas is performed, a film forming speed of a fifth substrate is recovered to be equal to a film forming speed of a first substrate.

Thus, when the modification processing operation according to the present invention is performed, the reduction of a film forming speed can be suppressed. In addition, when the modification processing operation according to the present invention is combined with the cleaning processing operation that has a longer process time than that of the modification processing operation, compared with the case of performing only the cleaning processing operation, a film forming speed can be prevented from being reduced in a state of improving the throughput of the whole apparatus.

When the substrate processing method or the substrate processing apparatus is configured as described above, ultraviolet light can be irradiated on silicon compound gas including carbon and hydrogen to process a substrate, and an adhered matter (reaction product), which is generated when processing the substrate and is adhered to a structure such as the inner wall of the processing chamber, can be processed with excited oxygen-containing gas to modify the adhered matter. Thus, when it is necessary to remove an adhered matter, the modification processing operation is performed to reduce the number of times of an adhered matter removing process, thereby improving the throughput and forming a high quality film.

The present invention also includes the following embodiments.

(Supplementary Note 1)

According to an embodiment of the present invention, there is provided a substrate processing method comprising: loading a substrate into a processing chamber; supplying silicon compound gas including carbon and hydrogen into the processing chamber; irradiating ultraviolet light on the silicon compound gas supplied into the processing chamber to process the substrate; unloading the processed substrate from the processing chamber; and processing an inside of the processing chamber with excited oxygen-containing gas.

When the substrate processing method is configured as described above, an adhered matter (reaction product) generated when irradiating the ultraviolet light on the silicon compound gas to process the substrate and adhered to a structure such as an inner wall of the processing chamber is processed with the excited oxygen-containing gas to modify it, that is, to oxidize a carbon component or hydrogen component of the adhered matter, and thus, remove it.

(Supplementary Note 2)

In the substrate processing method of Supplementary Note 1, the silicon compound gas may be TEOS (tetraethoxysilane: Si(OC₂H₅)₄), TMCTS (tetramethylcyclotetrasiloxane: [(CH₃)HSiO]₄), or OMCTS (octamethylcyclotetrasiloxane: Si₂O₂(CH₃)₈).

When the substrate processing method is configured as described above, by irradiating the ultraviolet light on the silicon compound gas, an SiO₂ film is formed on the substrate, and a carbon component or hydrogen component of the SiO₂ film can be oxidized to remove it.

(Supplementary Note 3)

In the substrate processing method of Supplementary Notes 1 and 2, the oxygen-containing gas may be, after being supplied into the processing chamber, excited by irradiating the ultraviolet light on the oxygen-containing gas.

When the substrate processing method is configured as described above, the oxygen-containing gas is excited in the processing chamber, so that the oxygen-containing gas can be easily used in a high activation level.

(Supplementary Note 4)

In the substrate processing method of Supplementary Notes 1 and 2, the oxygen-containing gas may be, before being supplied into the processing chamber, excited using a high frequency power application.

When the substrate processing method is configured as described above, the oxygen-containing gas is supplied into the processing chamber after being excited out of the processing chamber, and thus, the activation level of the oxygen-containing gas can be easily adjusted.

(Supplementary Note 5)

In the substrate processing method of Supplementary Notes 1 to 4, a device isolation region may be formed on the substrate.

When the substrate processing method is configured as described above, the occurrence of a void in the device isolation region formed on the substrate is suppressed to facilitate filling of an interlayer insulating film, and a carbon component or hydrogen component of the interlayer insulating film can be oxidized to remove it.

(Supplementary Note 6)

In the substrate processing method of Supplementary Notes 1 to 5, the oxygen-containing gas may be ozone.

When the substrate processing method is configured as described above, a production efficiency of active oxygen generated by exciting the oxygen-containing gas is increased. Accordingly, a process speed of the modification processing operation on a reaction product adhered to a structure such as the inner wall of the processing chamber can be improved.

(Supplementary Note 7)

According to another preferred embodiment of the present invention, there is provided a substrate processing method in a substrate processing apparatus including: a processing chamber configured to process a substrate; a ultraviolet light emitting part installed out of the processing chamber to irradiate ultraviolet light into the processing chamber; and a transmission window installed on a partition wall of the processing chamber to transmit the ultraviolet light, the substrate processing method comprising:

loading the substrate into the processing chamber; supplying silicon compound gas including carbon and hydrogen into the processing chamber; irradiating the ultraviolet light on the silicon compound gas supplied into the processing chamber to process the substrate; unloading the processed substrate from the processing chamber; and processing the transmission window with excited oxygen-containing gas.

When the substrate processing method is configured as described above, an adhered matter (reaction product) generated when irradiating the ultraviolet light on the silicon compound gas to process the substrate and adhered to the transmission window is processed with the excited oxygen-containing gas to modify it. That is, a carbon component or hydrogen component of the adhered matter is oxidized to remove it. Accordingly, an irradiation amount of the ultraviolet light on the substrate, which is reduced by the adhered matter, can be maintained in a constant range of a desired level or greater.

(Supplementary Note 8)

According to another preferred embodiment of the present invention, there is provided a substrate processing method in a substrate processing apparatus including: a processing chamber configured to process a substrate; a ultraviolet light emitting part installed out of the processing chamber to irradiate ultraviolet light into the processing chamber; and a transmission window installed on a partition wall of the processing chamber to transmit the ultraviolet light, the substrate processing method comprising:

a substrate processing step including: loading the substrate into the processing chamber; supplying silicon compound gas including carbon and hydrogen into the processing chamber; irradiating the ultraviolet light on the silicon compound gas supplied into the processing chamber to process the substrate; and unloading the processed substrate from the processing chamber; and

processing the transmission window with excited oxygen-containing gas,

wherein the substrate processing step is performed at a predetermined number of times, and then, the processing of the transmission window with the excited oxygen-containing gas is performed.

When the substrate processing method is configured as described above, an adhered matter (reaction product) generated when irradiating the ultraviolet light on the silicon compound gas to process the substrate and adhered to the transmission window is periodically processed with the excited oxygen-containing gas to modify it. Accordingly, an irradiation amount of the ultraviolet light on the substrate, which is reduced by the adhered matter, can be easily maintained in a constant range of a desired level or greater.

(Supplementary Note 9)

According to another preferred embodiment of the present invention, there is provided a substrate processing method comprising:

a substrate processing step including: loading a substrate into a processing chamber; supplying silicon compound gas including carbon and hydrogen into the processing chamber; irradiating the ultraviolet light on the silicon compound gas supplied into the processing chamber to process the substrate; and unloading the processed substrate from the processing chamber; and

processing a transmission window with excited oxygen-containing gas; and

a fluorine-containing gas processing step in which an inside of the processing chamber is processed with excited fluorine-containing gas, and then, the fluorine-containing gas is exhausted from the inside of the processing chamber,

wherein the substrate processing step is performed at a predetermined number of times, then, the processing of the transmission window with the excited oxygen-containing gas is performed, then, the substrate processing step is performed at a predetermined number of times, and then, the fluorine-containing gas processing step is performed.

When the substrate processing method is configured as described above, an adhered matter in the processing chamber, which cannot be removed in a modification processing operation using the oxygen-containing gas can be removed using the fluorine-containing gas processing step.

In addition, by combining the processing using the oxygen-containing gas with the fluorine-containing gas processing step to modify the adhered matter in the processing chamber, the number of process times of the fluorine-containing gas processing step having a longer process time than that of the processing using the oxygen-containing gas can be decreased, and thus, a process time of a substrate lot unit is decreased to improve the productivity.

(Supplementary Note 10)

According to another preferred embodiment of the present invention, there is provided a substrate processing apparatus comprising: a processing chamber configured to process a substrate; a first gas supply part configured to supply silicon compound gas including carbon and hydrogen into the processing chamber; a second gas supply part configured to supply oxygen-containing gas into the processing chamber; a ultraviolet light emitting part installed out of the processing chamber to irradiate ultraviolet light into the processing chamber; a transmission window installed on a partition wall of the processing chamber to transmit the ultraviolet light; and a control part,

wherein the control part performs, in a state where the substrate is disposed in the processing chamber, a first process of irradiating the ultraviolet light from the ultraviolet light emitting part on the silicon compound gas supplied from the first gas supply part into the processing chamber, and the control part performs, in a state where the substrate is disposed out of the processing chamber, a second process of processing an inside of the processing chamber with the oxygen-containing gas supplied from the second gas supply part into the processing chamber and excited.

When the substrate processing apparatus is configured as described above, an adhered matter generated when irradiating the ultraviolet light on the silicon compound gas to process the substrate and adhered to a structure such as an inner wall of the processing chamber can be processed with the excited oxygen-containing gas to modify it.

The first gas supply part includes the silicon compound gas source 13, the MFC 12, and the opening-closing valve 11. The second gas supply part includes the oxygen-containing gas source 23, the MFC 22, and the opening-closing valve 21.

(Supplementary Note 11)

According to another preferred embodiment of the present invention, there is provided a substrate processing apparatus comprising: a processing chamber configured to process a substrate; a first gas supply part configured to supply silicon compound gas including carbon and hydrogen into the processing chamber; a second gas supply part configured to supply oxygen-containing gas into the processing chamber; a ultraviolet light emitting part installed out of the processing chamber to irradiate ultraviolet light into the processing chamber; a transmission window installed on a partition wall of the processing chamber to transmit the ultraviolet light; and a control part,

wherein the control part performs, in a state where the substrate is disposed in the processing chamber, a first process of irradiating the ultraviolet light from the ultraviolet light emitting part on the silicon compound gas supplied from the first gas supply part into the processing chamber, and the control part performs, in a state where the substrate is disposed out of the processing chamber, a second process of processing an inside of the processing chamber with the oxygen-containing gas supplied from the second gas supply part into the processing chamber and excited, and the control part performs the first process at a predetermined number of times, and then, performs the second process.

When the substrate processing apparatus is configured as described above, an adhered matter (reaction product) generated when irradiating the ultraviolet light on the silicon compound gas to process the substrate and adhered to the transmission window is periodically processed with the excited oxygen-containing gas to modify it. Accordingly, an irradiation amount of the ultraviolet light on the substrate, which is reduced by the adhered matter, can be easily maintained in a constant range of a desired level or greater.

(Supplementary Note 12)

According to another preferred embodiment of the present invention, there is provided a substrate processing apparatus comprising: a processing chamber configured to process a substrate; a first gas supply part configured to supply silicon compound gas including carbon and hydrogen into the processing chamber; a second gas supply part configured to supply oxygen-containing gas into the processing chamber; a third gas supply part configured to supply fluorine-containing gas into the processing chamber; a fourth gas supply part configured to supply purge gas into the processing chamber; a ultraviolet light emitting part installed out of the processing chamber to irradiate ultraviolet light into the processing chamber; a transmission window installed on a partition wall of the processing chamber to transmit the ultraviolet light; and a control part,

wherein the control part performs, in a state where the substrate is disposed in the processing chamber, a first process of irradiating the ultraviolet light from the ultraviolet light emitting part on the silicon compound gas supplied from the first gas supply part into the processing chamber; the control part performs, in a state where the substrate is disposed out of the processing chamber, a second process of processing an inside of the processing chamber with the oxygen-containing gas supplied from the second gas supply part into the processing chamber and excited; the control part performs, in a state where the substrate is disposed out of the processing chamber, a third process in which the inside of the processing chamber is processed with the fluorine-containing gas supplied from the third gas supply part into the processing chamber, and then, the fluorine-containing gas is exhausted from the processing chamber, and simultaneously, the purge gas is supplied from the fourth gas supply part into the processing chamber; and the control part performs the first process at a predetermined number of times, then, performs the second process, then, the first process at a predetermined number of times, and then, performs the third process.

When the substrate processing apparatus is configured as described above, an adhered matter in the processing chamber, which cannot be removed in a modification processing operation using the oxygen-containing gas can be removed using the fluorine-containing gas processing step. In addition, by combining the processing using the oxygen-containing gas with the fluorine-containing gas processing step to modify the adhered matter in the processing chamber, the number of process times of the fluorine-containing gas processing step having a longer process time than that of the processing using the oxygen-containing gas can be decreased, and thus, a process time of a substrate lot unit is decreased to improve the productivity.

(Supplementary Note 13)

According to another preferred embodiment of the present invention, there is provided a semiconductor device manufacturing method comprising: loading a semiconductor substrate into a processing chamber; supplying silicon compound gas including carbon and hydrogen into the processing chamber; irradiating ultraviolet light on the silicon compound gas supplied into the processing chamber to process the substrate; unloading the processed substrate from the processing chamber; and processing an inside of the processing chamber with excited oxygen-containing gas.

When the substrate processing method is configured as described above, an adhered matter (reaction product) generated when irradiating the ultraviolet light on the silicon compound gas to process the substrate and adhered to a structure such as an inner wall of the processing chamber is processed with the excited oxygen-containing gas to modify it, that is, to oxidize a carbon component or hydrogen component of the adhered matter, and thus, remove it.

The third gas supply part includes the cleaning gas source 33, the MFC 32, and the opening-closing valve 31. The fourth gas supply part includes the inert gas source 43, the MFC 42, and the opening-closing valve 41.

In addition, in the current embodiment, a semiconductor device is exemplified, but the present invention is not limited thereto, and thus, a substrate such as an organic electroluminescent (EL) may also be effectively exemplified.

What is claimed is:

1. In a substrate processing apparatus including: a processing chamber configured to process a substrate; a ultraviolet light emitting part installed out of the processing chamber to irradiate ultraviolet light into the processing chamber; and a transmission window installed on a partition wall of the processing chamber to transmit the ultraviolet light, a substrate processing method comprising:
loading the substrate into the processing chamber;
supplying silicon compound gas including carbon and hydrogen into the processing chamber;
irradiating the ultraviolet light on the silicon compound gas supplied into the processing chamber to process the substrate;
unloading the processed substrate from the processing chamber; and
processing the transmission window with excited oxygen-containing gas.

2. The substrate processing method of claim 1, wherein the loading of the substrate, the supplying of the silicon compound gas, the irradiating of the ultraviolet light, and the unloading of the processed substrate are set as a substrate processing step, and the substrate processing step is performed at a predetermined number of times, and then, the processing of the transmission window with the excited oxygen-containing gas is performed.

3. The substrate processing method of claim 2, comprising the substrate processing step,
the processing of the transmission window with the excited oxygen-containing gas, and
a fluorine-containing gas processing step in which an inside of the processing chamber is processed with excited fluorine-containing gas, and then, the fluorine-containing gas is exhausted from the inside of the processing chamber,
wherein the substrate processing step is performed at a predetermined number of times, then, the processing of the transmission window with the excited oxygen-containing gas is performed, then, the substrate processing step is performed at a predetermined number of times, and then, the fluorine-containing gas processing step is performed.

4. The substrate processing method of claim 1, wherein the silicon compound gas is TEOS (tetraethoxysilane: Si(OC₂H₅)₄), TMCTS (tetramethylcyclotetrasiloxane: [(CH₃)HSiO]₄), or OMCTS (octamethylcyclotetrasiloxane: Si₂O₂(CH₃)₈).

5. The substrate processing method of claim 4, wherein the loading of the substrate, the supplying of the silicon compound gas, the irradiating of the ultraviolet light, and the unloading of the processed substrate are set as a substrate processing step, and the substrate processing step is performed at a predetermined number of times, and then, the processing of the transmission window with the excited oxygen-containing gas is performed.

6. The substrate processing method of claim 1, wherein the oxygen-containing gas is ozone.

7. The substrate processing method of claim 6, wherein the loading of the substrate, the supplying of the silicon compound gas, the irradiating of the ultraviolet light, and the unloading of the processed substrate are set as a substrate processing step, and the substrate processing step is performed at a predetermined number of times, and then, the processing of the transmission window with the excited oxygen-containing gas is performed.

8. The substrate processing method of claim 1, wherein in the processing of the transmission window with the excited oxygen-containing gas, the oxygen-containing gas is supplied into the processing chamber, and then, the ultraviolet light is irradiated on the oxygen-containing gas.

9. The substrate processing method of claim 8, wherein the loading of the substrate, the supplying of the silicon compound gas, the irradiating of the ultraviolet light, and the unloading of the processed substrate are set as a substrate processing step, and the substrate processing step is performed at a predetermined number of times, and then, the processing of the transmission window with the excited oxygen-containing gas is performed.

10. The substrate processing method of claim 1, wherein the oxygen-containing gas is, before being supplied into the processing chamber, excited using a high frequency power application.

11. The substrate processing method of claim 10, wherein the loading of the substrate, the supplying of the silicon compound gas, the irradiating of the ultraviolet light, and the unloading of the processed substrate are set as a substrate processing step, and the substrate processing step is performed at a predetermined number of times, and then, the processing of the transmission window with the excited oxygen-containing gas is performed.

12. The substrate processing method of claim 1, wherein a device isolation region is formed on the substrate.

13. The substrate processing method of claim 12, wherein the loading of the substrate, the supplying of the silicon compound gas, the irradiating of the ultraviolet light, and the unloading of the processed substrate are set as a substrate processing step, and the substrate processing step is performed at a predetermined number of times, and then, the processing of the transmission window with the excited oxygen-containing gas is performed.

14. A substrate processing apparatus comprising: a processing chamber configured to process a substrate; a first gas supply part configured to supply silicon compound gas including carbon and hydrogen into the processing chamber; a second gas supply part configured to supply oxygen-containing gas into the processing chamber; a ultraviolet light emitting part installed out of the processing chamber to irradiate ultraviolet light into the processing chamber; a transmission window installed on a partition wall of the processing chamber to transmit the ultraviolet light; and a control part,
wherein the control part performs, in a state where the substrate is disposed in the processing chamber, a first process of irradiating the ultraviolet light from the ultraviolet light emitting part on the silicon compound gas supplied from the first gas supply part into the processing chamber, and the control part performs, in a state where the substrate is disposed out of the processing chamber, a second process of processing an inside of the processing chamber with the oxygen-containing gas supplied from the second gas supply part into the processing chamber and excited.

15. A semiconductor device manufacturing method comprising:
loading a semiconductor substrate into a processing chamber;
supplying silicon compound gas including carbon and hydrogen into the processing chamber;
irradiating ultraviolet light on the silicon compound gas supplied into the processing chamber to process the substrate;
unloading the processed substrate from the processing chamber; and
processing an inside of the processing chamber with excited oxygen-containing gas.
